(19) United States
(12) Patent Application Publication
(10) Pub. No.: US 2007/0120254 A1
(43) Pub. Date: May 31, 2007

(54) Semiconductor device comprising a pn-heterojunction

(75) Inventors: Godefridus Adrianus Maria Hurkx, Eindhoven (NL); Prabhat Agarwal, Leuven (BE); Abraham Rudolf Balkenende, Eindhoven (NL); Petrus Hubertus Cornelis Magnee, Leuven (BE); Melanie Maria Hubertina Wagemans, Eindhoven (NL); Erik Petrus Antonius Maria Bakkers, Eindhoven (NL); Erwin Adolf Hijzen, Leuven (BE)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.C.

(21) Appl. No.: 10/584,038

(22) PCT Filed: Dec. 20, 2004
(86) PCT No.: PCT/IB04/52864

§ 371 Date: Jun. 21, 2006

(30) Foreign Application Priority Data
Dec. 23, 2003 (EP) 03104933.1
Jul. 20, 2004 (EP) 0410461.2

(51) Int. Cl. H01L 23/48

(52) U.S. Cl. 257/745

(57) ABSTRACT

An electric device is disclosed comprising a pn-heterojunction (4) formed by a nanowire (3) of 111-V semiconductor material and a semiconductor body (1) comprising a group IV semiconductor material. The nanowire (3) is positioned in direct contact with the surface (2) of the semiconductor body (1) and has a first conductivity type, the semiconductor body (1) has a second conductivity type opposite to the first conductivity type, the nanowire (3) forming with the semiconductor body (1) a pn-heterojunction (4). The nanowire of III-V semiconductor material can be used as a diffusion source (5) of dopant atoms into the semiconductor body. The diffused group III atoms and/or the group V atoms from the III-V material are the dopant atoms forming a region (6) in the semiconductor body in direct contact with the nanowire (3).

The invention relates to an electric device comprising:
a semiconductor body comprising a group IV semiconductor material having a surface,
a nanostructure of a III-V semiconductor material.

The invention further relates to a method of forming a pn-heterojunction, the method comprising the steps of:
forming a nanostructure of a second semiconductor material on a surface of a semiconductor body of a first semiconductor material, the first semiconductor material comprising at least one element from group IV of the periodic system and the second semiconductor material being a III-V material.

In this application a nanowire is a body having at least one lateral dimension between 0.5 and 100 nm, more in particular between 1 and 50 nm. Preferably the nanowire has two lateral dimensions in the range mentioned above.

These dimensions can not be made, or at least not made easily with photolithography, although these dimensions are highly desirable in the drive for miniaturization of IC's.

The semiconductor industry can be divided into three main sub-industries based upon the three most applied semiconductor technologies: silicon (Si), gallium arsenide (GaAs) and indium phosphide (InP). The silicon technology is the most dominant technology in terms of application and maturity, however the physics of silicon limits its application in high-frequency applications and optical applications, where gallium arsenide and indium phosphide are the most appropriate materials. The large lattice mismatch and thermal mismatch between silicon being a group IV semiconductor material, and gallium arsenide and indium phosphide both being group III-V materials render the integration on a single chip difficult for the three materials.

Integration of group III-V semiconductors on silicon substrates has received significant interest due to the potential of combining complementary IIIV device technologies and performances, such as opto-electronics and high-frequency devices, with the silicon technology, e.g. the CMOS technology.

Group III-V semiconductor materials may be accommodated on, or integrated with, group IV semiconductor materials by using one or more buffer layers.

In the US patent application 2003/0038299 mono-crystalline GaAs layers may be grown on a silicon substrate by using two subsequent buffer layers, e.g. silicon oxide and strontium titanate. These buffer layers are used to accommodate some of the lattice mismatch between the layers.

Disadvantages of applying buffer layers, as done in the above-mentioned prior art, may include that no electrical contact is present between the upper layer and the substrate, the number of distinct process steps in order to form the buffer layers, that it is expensive to growth the buffer layers, etc.

Beside the lattice mismatch there is the problem of anti phase domains. In the article “Anti-domain-free GaP, grown in atomically flat (001) Si sub-um-sized openings”, B. J. Ohlsson et al., Applied physics letters, 17 Jun. 2002, volume 80, number 24, p. 4546-4548, a method is disclosed for the growth of GaP nanocrystals on Si (001). In the method selective-area epitaxy of GaP on atomically flat Si is applied in masked openings. Monocrystalline GaP nanocrystals were grown in a chemical-beam epitaxy chamber at a temperature of 700° C. Before growth, the Si surface was exposed to phosphorous.

The problem with this chemical-beam-epitaxy method is the formation of anti phase domains (APDs) during heterogrowth of the polar III-V material on the nonpolar IV material. On (001) surfaces, the two possible phases differ by a 90° in plane rotation. At the boundary between two APDs, an antiphase boundary (APB) is created. The APB can be electrically active and act as a nonradiative recombination center.

Such a recombination center generates leakage when applied in pn junctions.

Moreover the nanocrystals are embedded in the GaP layer, so that it is not possible to make an electrical contact to an individual nanocrystal. It is therefore very difficult to manufacture an integrated circuit of semiconductor elements, in which a semiconductor element comprises a single nanocrystal.

It is an object of the invention to provide an electric device of the type mentioned in the opening paragraph that has increased functionality.

The object of the invention is achieved in that the nanostructure is a nanowire being positioned in direct contact with the surface and having a first conductivity type, the semiconductor body having a second conductivity type opposite to the first, the nanowire forming with the semiconductor body a pn-heterojunction.

Nanowires of III-V semiconductor material have attractive new electrical and opto-electrical properties. Because of the small size of the nanowire quantum confinement phenomena may occur. Electrical transport and optical properties of such a quantum wire can be designed by a proper choice of material and dimensions. In particular nanowires of III-V semiconductor material with a direct bandgap have attractive optical and electro-optical properties. Nanowires of compound semiconductors such as GaAs, GaP, GaAsP, InAs, InP, InAsP cover a wide range in bandgap and mobility. Moreover nanowires allow ultra-high speed and integration density.

According to the invention, a pn-heterojunction between a nanowire of III-V material and a semiconductor comprising a group IV element, such as Si or Ge, is formed. The nanowire forms one part of the pn-heterojunction, being n-type or p-type. The other part of the pn-heterojunction is formed respectively by the p-type or n-type semiconductor body. The electrical properties of the nanowire are of importance. In particular for high speed applications, the resistivity should be low, so that a high n-type or p-type dopant concentration is favourable. The III-V nanowire allows the combination of light with a fine-tuned wavelength combined with cheap VLSI technology in silicon for logic and memory. Nanowires connected to conventional electronics allow increased functionality of an integrated circuit. The pn-heterojunction is an important building block for several devices such as opto-electronic devices, e.g. light emiting diodes, and heterojunction bipolar transistors.

In an advantageous embodiment, the nanowire of III-V material is a diffusion source of dopant atoms into the semiconductor body. The III-V material may include more than two elements from the periodic system, i.e. it may be a binary, a ternary, or a quaternary compound, or may be a compound containing more than five elements.

The semiconductor body may e.g. be a group IV semiconductor material, such as silicon or silicon-germanium (SiGe). The semiconductor body need not be a substrate of a bulk material. The semiconductor body may be a top layer supported by a bulk material of the same or a different material.

The invention is based on the insight that group III and/or group V atoms from the III-V material are dopant atoms in the group IV semiconductor material and that the group III and group V atoms have different diffusion coefficients and solid solubilities in the group IV semiconductor material.

A group III atom (e.g. Ga) is a p-type dopant atom in the group IV semiconductor material, while a group V atom (e.g. P) is an n-type dopant atom in the group IV semiconductor (e.g. Si or Ge). Group III and/or group V atoms from the III-V material are diffused into the group IV semiconductor material. The group III or group V atoms can originate from a broken chemical bond in the III-V material, which may occur when the III-V material is heated above a critical temperature. Atoms with the highest diffusion coefficient in the group IV semiconductor form a pn junction with the semiconductor body, which semiconductor body has n-type or p-type dopant atoms of opposite conductivity type of the diffused dopant atoms.

If the solid solubility of the atoms with the lower diffusion coefficient is higher than the solid solubility of the atoms with the higher diffusion coefficient, pn junctions are formed inside a p-type or n-type semiconductor body. This means that a pnp or npn dopant profile is formed, which can be used advantageously in the manufacturing of bipolar transistors.

Preferably there is a region in the semiconductor body in direct contact with the nanowire, which has the same conductivity type as the nanowire. This may be an ultra-shallow junction of very small lateral dimensions, e.g.in a range below 20 nm. Such a small dimensions can not be made with photolithography in a reliable way. The pn junction is now located inside the smiconductor body. The interface between the nanowire and the semiconductor is no longer the place of the metallurgical junction, so that the electrical properties of the pn-junction can be improved.

The nanowire may be removed after formation of the shallow junction. Instead, a metal contact can be used to further reduce the contact resistance. In order to position the metal contact on the small junction, it is desirable to form spacers around the nanowire, before selective removal of the III-V nanowire from the semiconductor body.

Because of the small area of the junction, the depletion capacitance can be very small, which allows the manufacture of ultra-high speed devices. Because the dimensions are of the order of te Bloch wavelength, quantum size effects can be advantageously be used in the design of devices.

The III-V material may comprise an excess of the group III atoms and/or the group V in the nanowire e.g. built in during epitaxial growth.

The nanowire can be epitaxially grown with a vapour-liquid-solid (VLS) growth method, such as a laser-assisted cathalytic growth method, directly on the surface of the semiconductor body. The synthesis of a broad range of binary and ternary III-V nanowires is highly determined by the target composition and the growth temperature.

In an advantageous embodiment of the method on the surface of the semiconductor body local areas of metal are provided. The metal is molten, forming a droplet that can serve as a cathalyst to grow nanowires with the vapour liquid solid growth method, such as laser ablation. The nanowire is grown below the metal droplet on the surface of the semiconductor body. A liquid alloy droplet containing the metal and the semiconductor material to be grown is located at the tip of the wire and moves along with the growing end of the wire. This method is compatible with existing IC technology. It is also possible to obtain droplets of metal with the aid of a colloidale solution of a metal (compound).

Although the ternary and quaternary III-V materials give more freedom to adapt the lattice constant to the semiconductor body, the invention is based on the insight that by providing a nanowire of III-V material, instead of an overlayer of III-V material, problems with e.g. lattice mismatch between the two materials may be reduced. A possible lattice mismatch need not cause strain to build up in the nanowire. Strain may be relieved on the surface of the nanostructure, thereby rendering a nanostructure with very few defects, or even defect-free, possible, and further rendering possible an epitaxial relationship between the nanostructure and the substrate.

The invention is further based on the insight that it is not possible to grow epitaxial overlayers above a certain thickness of certain materials on top of certain substrates. For example, it is not possible to grow an epitaxial overlayer with a thickness larger than approximately 20 nm of InP on a substrate of group IV such as SiGe due to the strain resulting from the lattice mismatch. By providing nanowires in epitaxial relationship with a substrate, it may be possible to grow wires with larger thickness than what may be obtained with an overlayer of the same material. Nanowires of InP structures with longitudinal dimensions larger than 20 nm may be brought into epitaxial relationship with a SiGe substrate because due to the limited lateral dimension the strain is relatively small and may be relaxed at the surface of the nanowire.

The nanowire may be an elongated structure projecting away from the substrate. The elongated nanowire may possess a specific aspect ratio, i.e. with a specific length-to-diameter ratio. The aspect ration may be larger than 10, such as larger than 25, such as larger than 50, such as larger than 100, such as larger than 250. The diameter may be obtained perpendicularly to the longitudinal direction of the nanowire.

The nanowire may be in electrical contact with the substrate. The electrical contact may be a so-called Ohmic contact, an expression which is used in the art for a low resistance contact. The resistance between the nanowire and the substrate may at room temperature be below 10⁻⁵ Ohm cm², such as below 10⁻⁶ Ohm cm², such as below 10⁻⁷ Ohm cm², such as below 10⁻⁸ Ohm cm², such as below 10⁻⁹ Ohm cm², or even lower. It is an advantage to obtain as low a resistance as possible in order to reduce e.g. heat dissipation in the contact area.

The lattice mismatch between the substrate and the nanostructure may be smaller than 10%, such as smaller than 8%, such as smaller than 6%, such as smaller than 4%, such as smaller than 2%. The lattice mismatch may be larger than 0.1%, larger than 1% and/or larger than 2%. As an example of lattice mismatches between group III-V and group IV semiconductor materials, the lattice mismatch between InP and Ge and Si is 3.7% and 8.1%, respectively. It is an advantage that it may be possible to provide epitaxial relationship between two materials having such relative large lattice mismatches. It is expected that the larger the lattice mismatch, the thinner the nanowires have to be in order to obtain an epitaxial relationship with the substrate.

The nanowire may be a substantially single-crystal nanowire. It may be advantageous to provide single-crystal nanowire, e.g. in relation with theoretical elaboration of current transport through the nanowire, or other types of theoretical support or insight into properties of the nanowire. Further, other advantages of substantially single-crystal nanowire include that a device with a more well-defined operation may be achieved, e.g. a transistor device with a better defined voltage threshold, with less leak current, with better conductivity, etc. may be obtained, than for devices based on non-single crystal nanowires.

The nanowire may be the functional component of a device selected from the group consisting of phonon bandgap devices, quantum dot devices, thermoelectric devices, photonic devices, nanoelectromechanical actuators, nanoelectromechanical sensors, field-effect transistors, infrared detectors, resonant tunneling diodes, single electron transistors, infrared detectors, magnetic sensors, light emitting devices, optical modulators, optical detectors, optical waveguides, optical couplers, optical switches, and lasers.

A plurality of nanowires may be arranged in an array. By arranging the nanowires in an array, integrated circuit devices comprising a multitude of single electronic components, such as a multitude of transistor components, may be provided. The array of the nanowires may be provided in combination with selection lines or a selection grid for addressing individual nanowires, or a group of nanowires.

According to a second aspect of the invention, there is provided a method of forming a heterojunction, the method comprising the steps of:

forming a nanostructure (1,44,51) of a second semiconductor material on a surface of a semiconductor body (2,42,50) of a first semiconductor material,

the first semiconductor material comprising at least one element from group IV of the periodic system and the second semiconductor material being a III-V material,

wherein the nanostructure is a nanowire grown on the surface of the semiconductor body and receiving a first conductivity type, the semiconductor body having a second conductivity type opposite to the first conductivity type, the nanowire forming with the semiconductor a pn-heterojunction.

The nanowire may be grown according to the vapour-liquid-solid (VLS) growth mechanism. In VLS growth, a metal particle is provided onto the substrate at positions where the nanowire is to be grown. The metal particles may be a metal or an alloy comprising a metal selected from the group consisting of: Fe, Ru, Co, Rh, Ni, Pd, Pt, Cu, Ag, Au, Ti.

The nanowire may however also be grown using different growth methods. For example, the nanowire may be grown epitaxially in a contact hole from a vapour phase or. liquid phase, i.e. a hole in a dielectric layer covering the substrate except for the position of the nanowire.

Reference made to a nanowire, the nanowire, one nanowire etc. does not indicate that reference is made only to a single nanowire. More than one nanowire, such as a plurality of nanowires is also covered by such references.

These and other aspects, features and/or advantages of the invention will be apparent from and elucidated with reference to the embodiments described hereinafter.

Embodiments of the invention will be described, by way of example only, with reference to the drawings, in which:

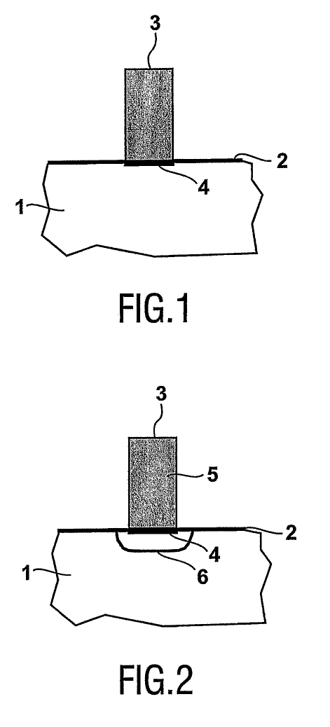

FIG. 1 shows a schematic of a n-type nanowire of III-V semiconductor material on a p-type semiconductor body forming a pn-heterojunction according to the invention.

FIG. 2 shows an n-type region below the nanowire formed by outdiffusion from the III-V material.

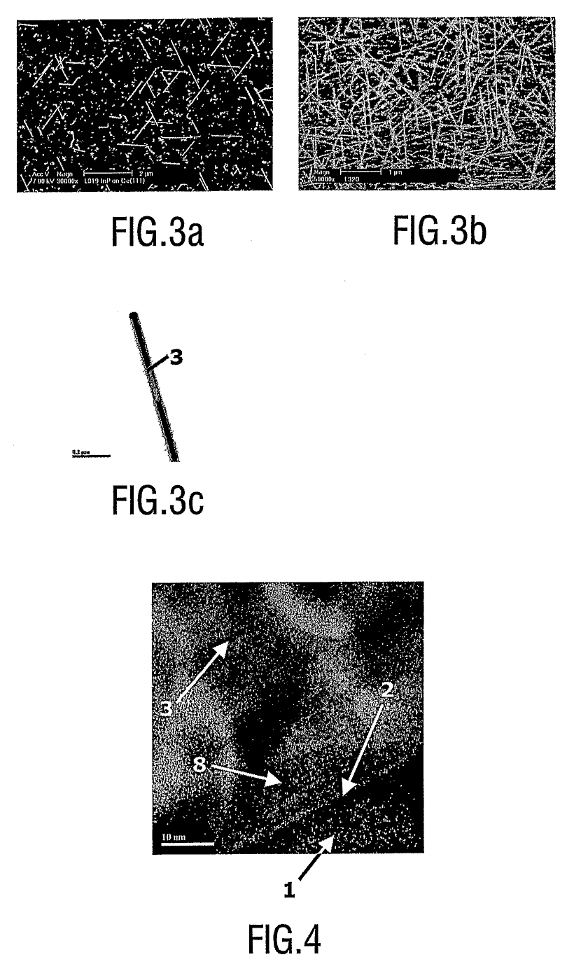

FIG. 3a-c show SEM images of InP nanostructures grown on Ge(111),

FIG. 4 shows a HRTEM image of the interface between an InP nanostructure in contact with Ge(111),

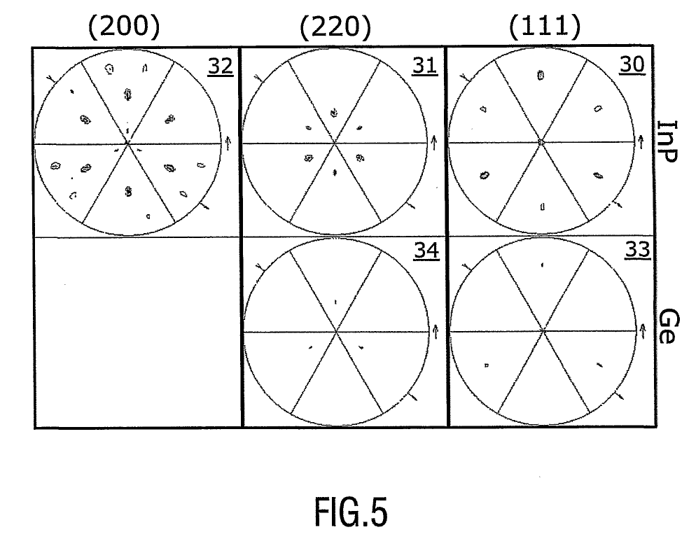

FIG. 5 shows XRD pole diagrams of InP nanostructures grown on Ge(111).

In FIG. 1 a p type (100) semiconductor body (1) with a resistivity of 3-5 Ohmcm is provided with a nanowire of III-V material. In this embodiment the nanowire (3) is InP. The invention works equally well for GaAs, GaP, GaAsP, InAs, and InAsP GaP and GaAs nanowires. On the surface (2) of the p-type semiconductor body (1) a dielectric layer of silicon oxide is deposited. On top of the silicon oxide layer a photoresist layer such as PMMA is provided. The photoresist layer is exposed with the aid of photolithography or e-beam lithography.

After development of the photoresist the silicon oxide layer is removed in the open areas of the resist layer, preferably by wet chemical etching in an HF solution. The semiconductor body is now visible in the openings in the silicon oxide.

On the patterned photoresist layer a metal layer is evaporated. In this example the metal layer is a 10 nm thick gold layer, but the metal layer can also be a thin Ni or Ti layer. Requirement for the thin metal layer is that it should not react with the photoresist layer or heat the resist too much so that the resist can't be removed afterwards anymore. Preferably, the melting point of the metal is relatively low.

In a lift-off process the photoresist layer is removed together with the metal layer that is present on the resist layer. After the lift-off process, the Si body is provided with small areas of metal.

In a next step the areas of metal, in this case Au, are heated at an elevated temperature so that a droplet is formed of Au. In this example some Si is dissolved in the Au.

Subsequently an InP nanowire is grown on the Si semiconductor body by means of a vapour-liquid-solid process. The substrate was maintained at a temperature in the range of 450 to 495° C. while an In and P concentration was established using laser ablation, and maintained during the growth of the nanowires.

During growth the liquid alloy droplet containing the Au and Si is located at the tip of the wire and moves along with the growing end of the wire. The nanowire grows along the Si [100] direction. During growth Si atoms diffuse into the InP nanowire. Si is an n-type dopant atom in InP, so that the InP nanowire is n-type after the growth process. In this way a pn-heterojunction (4) is formed. The diffusion of In and/or P atoms from the InP into the Si is negligible small during growth of the nanowire.

The InP nanowire can be used as diffusion source (5) for dopant atoms into the Si.

To circumvent that P may evaporate from the surface of the nanowire, the nanowire is embedded in a dielectric, such as a deposited PECVD TEOS layer. In a subsequent anneal step, P atoms from the InP are diffused into the Si semiconductor body. The anneal is done in a temperature range above 600° C. In this example a rapid thermal anneal (RTP) was used at a temperature of 900° C., during 1 sec. The diffusion coefficient of P in Si (2×10⁻¹⁵ cm²/s) and solid solubility of P in Si (7×10²⁰ at/cm³) is much higher than the diffusion coefficient and solid solubility of In in Si, so that P atoms form an n-type region (6) below the nanowire in the p-type Si semiconductor body. In the anneal step, Si atoms diffuse into the nanowire, so that the nanowire is highly n-type doped, typical of the order of the solid solubility of Si in InP. In this way a highly doped n-type nanowire is obtained with excellent electrical properties (such as low resistivity, monocristalline material without defects).

The pn-junction is now located in the Si semiconductor body. The pn-junction is not longer located at the interface between the nanowire and the semiconductor body, which interface is difficult to control and is not always perfectly clean. By positioning the pn-junction in the semiconductor body, leakage currents are reduced significantly, because the depletion layer of the pn junction is now located in the semiconductor body.

The nanowire may be removed after junction formation and spacer formation. For the spacer formation, the deposited TEOS layer can be used. In a plasma etch of a fluorine containing gas, such as CF₄, the TEOS layer is etched anisotropically and spacers are formed. The III-V material of the nanowire can be selectively removed from the group IV semiconductor material e.g. by wet chemical etching. The nanowire can be replaced by a metal, such as Ni, so that a metal contacted ultra-shallow highly doped junction is formed, which may be the emitter of a bipolar transistor.

In another embodiment the III-V semiconductor material of the nanowire (3) is GaAs and the semiconductor body (1) is n-type silicon. The Ga atom has a higher diffusion coefficient in Si than As, but a lower solid solubility. In a temperature range above 950° C., the Ga atoms form a p-type region (6) in the n-type Si semiconductor body. If the temperature is raised above 1000° C., the As diffuses into the Si as well, overdoping the Ga atoms. The Ga atoms diffuse faster than the As atoms, so that a np junction is formed in the n-type Si semiconductor body.

It is also possible to incorporate dopant atoms in GaAs during eptiaxial growth of the nanowire, such as GaAs with B, or GaAs with P.

These dopant atoms are diffused from the GaAs diffusion source (5) into the group IV semiconductor body, forming a shallow highly doped p-type or n-type region. After diiffusion of B from the boron doped GaAs diffusion source, a p-type region is formed in silicon (or e.g. germanium or a compound of these elements). Alternatively, an n-type region is formed in the silicon (or e.g. germanium or a compound of these elements) after diffusion from the phosphorous-doped GaAs diffusion source. The temperature range for outdiffusion of B or P from the GaAs diffusion source is typical in a temperature range above 600° C.

In FIGS. 3 to 5, various aspects of InP nanowires (group III-V) grown on Ge(111) (group IV) are illustrated.

The nanowires were growth using the VLS-growth method. The equivalent of a 2 Angstrom (Å) gold layer was deposited on a cleaned Ge(111) substrate. The substrate was before the deposition of gold cleaned by dipping it in a buffered HF solution. The substrate was maintained at a temperature in the range 450 to 495° C. while an In and P concentration was established using laser ablation, and maintained during the growth of the nanowires.

FIG. 3(a) is a top view scanning electron microscopy (SEM) image. The nanowires are imaged bright, and it is clear that the nanowires have a crystallographic three-fold symmetry orientation. In FIG. 3(b) a side view is provided, and it may be seen that most of the nanowires are grown vertically on the substrate, even though some of the nanowires are at an angle of 35° with respect to the substrate. In FIG. 3(c) a single wire 3 is imaged.

In FIG. 4 a high-resolution transmission electron microscopy (HRTEM) image of an InP wire 3 on a Ge(111) substrate 1 is illustrated. An atomically sharp interface 2 between the wire and the substrate is readily recognized. Some stacking faults 8 (3 to 5 twinning planes) are present, however the stacking faults are grown out after 20 nm. Further, it may be observed that the Ge lattice (direction) continues in the InP lattice, meaning the wires really grow epitaxially.

The epitaxial relationship between the nanowire and the substrate is further elaborated upon in connection with FIG. 5. In FIG. 5 X-ray diffraction (XRD) pole diagrams of InP nanostructures grown on Ge(111) are shown.

In the figure five sets of spots are shown, the (111), (220) and (200) spots are shown for InP 30, 31, 32, whereas only the (111) and (220) spots are shown for Ge 33, 34. The reflections of the InP crystal appear at identical orientations with respect to the Ge reflections. Thus, the wires indeed grow epitaxially. Besides the identical orientation also a 180 degrees in-plane rotation can be observed. This is either due to the fact that InP crystals consist of two atoms and Ge of one, and the wires can grow in two orientations on the Ge, or that a rotational twin in the [111] direction is present.

InP nanowires grown on Ge(111) are provided as an example, different types of nanowires may be grown on the same or different substrates within the scope of the present invention. As a specific example, nanowires may also be grown on the technological important surface of Si(100) or Ge(100). In this case the nanowires then grow along the [100] direction.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of other elements or steps than those listed in a claim. The word “a” or “an” preceding an element does not exclude the presence of a plurality of such elements.

1. An electric device comprising:
a semiconductor body comprising a group IV semiconductor material having a surface
a nanostructure of a III-V semiconductor material,
characterised in that the nanostructure is a nanowire being positioned in direct contact with the surface and having a first conductivity type, the semiconductor body having a second conductivity type opposite to the first conductivity type, the nanowire forming with the semiconductor body a pn-heterojunction.

2. An electric device as claimed in claim 1, characterised in that the III-V material is a diffusion source of dopant atoms into the semiconductor body.

3. An electric device as claimed in claim 2, characterised in that the diffusion source contains the group III atoms and/or the group V atoms from the III-V material.

4. An electric device as claimed in claim 1, characterised in that there is a region in the semiconductor body in direct contact with the nanowire which has the same conductivity type as the nanowire.

5. An electric device as claimed in claim 2, characterised in that the III-V material comprises an excess of the group III atoms and/or the group V atoms of the III-V material, which excess atoms form the dopant atoms in the semiconductor body.

6. A device according to claim 1, characterised in that the nanowire is in epitaxial relationship with the semiconductor body and the materials have a mutual lattice mismatch.

7. A device according to claim 2, characterised in that the resistance between the nanowire and the semiconductor body is below 10⁻⁵ Ohm cm².

8. A device according to claim 1, characterised in that a lattice mismatch between the semiconductor body and the nanowire is smaller than 10%.

9. A device according to claim 1, characterised in that the nanowire is a substantially single-crystal nanowire.

10. A device according to claim 1, characterised in that a plurality of nanowires are arranged in an array.

11. A method of forming a pn-heterojunction, the method comprising the steps of:
forming a nanostructure of a second semiconductor material on a surface of a semiconductor body of a first semiconductor material, the first semiconductor material comprising at least one element from group IV of the periodic system and the second semiconductor material being a III-V material,
characterised in that the nanostructure is a nanowire grown on the surface of the semiconductor body and receiving a first conductivity type, the semiconductor body having a second conductivity type opposite to the first conductivity type, the nanowire forming with the semiconductor body a pn-heterojunction.

12. A method as claimed in claim 11, characterised in that the nanowire of III-V semiconductor material is used as a diffusion source of dopant atoms into the semiconductor body.

13. A method as claimed in claim 12, characterised in that group III atoms and/or the group V atoms from the III-V material are the dopant atoms.

14. A method as claimed in claim 11, characterised in that the nanowire is grown in epitaxial relationship with the semiconductor body.

15. A method as claimed in claim 14, characterised in that the nanowire is grown according to the vapour-liquid-solid (VLS) growth method.

16. A method as claimed in claim 14, characterised in that an excess of the group III atoms and/or the group V atoms are grown in the III-V semiconductor material, which excess atoms are diffused into the semiconductor body.

17. A method as claimed in claim 14, characterised in that at least one element of the periodic system is incorporated in the III-V semiconductor material of the nanowire, which element is diffused into the group IV semiconductor material, forming an n-type or p-type dopant atom.

18. A method as claimed in claim 11, characterised in that the dopant atoms form a region in the semiconductor body in direct contact with the nanowire.

19. A method as claimed in claim 11, characterised in that the III-V semiconductor material of the nanowire is heated above 600° C.

20. A method as claimed in claim 19, characterised in that the nanowire is embedded in a dielectric before heating.

21. A method as claimed in claim 12, characterised in that the nanowire is selectively removed after being used as diffusion source.
